(19) United States
(12) Patent Application Publication
(10) Pub. No.: US 2025/0261561 A1
(43) Pub. Date: Aug. 14, 2025

(54) BASE FOR PIEZOELECTRIC DEVICE AND PIEZOELECTRIC DEVICE

(71) Applicant: NIHON DEMPA KOGYO CO., LTD., Tokyo (JP)

(72) Inventor: Shuichi MIZUSAWA, Saitama (JP)

(73) Assignee: NIHON DEMPA KOGYO CO., LTD., Tokyo (JP)

(21) Appl. No.: 19/047,597

(22) Filed: Feb. 6, 2025

(30) Foreign Application Priority Data
Feb. 13, 2024 (JP) 2024-019453

(51) Int. Cl. H10N 30/88; H10N 30/87

(52) U.S. Cl. CPC H10N 30/88; H10N 30/875

(57) ABSTRACT

A base for piezoelectric device includes a substrate made of glass or crystal, a mounting pattern, a frame-shaped wall portion, a contact portion, and a second metal film. The frame-shaped wall portion is disposed in a part along an edge of the substrate on the first surface and made of a material identical to a material of the substrate. The wall portion is bonded to the substrate with a first metal film for intermetallic bonding. The external mounting terminal disposed on a second surface that is an opposite surface from the first surface of the substrate. The contact portion is insulated from the first metal film in a region directly below the wall portion. The contact portion passing through the substrate to electrically connect the mounting pattern to the external mounting terminal. The second metal film forms intermetallic bonding with the contact portion to form airtightness of the contact portion.

### CROSS REFERENCE TO RELATED APPLICATIONS

This application is based on and claims priority under 35 U.S.C. § 119 to Japanese Patent Application No. 2024-019453, filed on Feb. 13, 2024, the entire content of which is incorporated herein by reference.

### TECHNICAL FIELD

This disclosure relates to a base for a piezoelectric device and a piezoelectric device including the same.

### DESCRIPTION OF THE RELATED ART

In a piezoelectric device, a container for containing a piezoelectric element is indispensable. Therefore, various kinds of containers, such as metal containers, ceramic containers, or containers made of glass or crystal, are used or studied for quartz-crystal devices as a type of piezoelectric device. Especially, surface mount type containers are frequently used for mass-production type quartz-crystal devices because the demand for surface mount type containers is high.

A typical container that is a surface mount type and suitable for mass production is a ceramic container. Specifically, it is a container in which a ceramic base and a metal or ceramic lid are bonded together. For example, JP2007-274071A discloses a ceramic base in which a bottom plate made of ceramic material having a rectangular shape in planar view and a dike portion made of ceramic material laminated on the bottom plate are integrally baked (paragraph 0026, FIG. 1, and the like).

As an example of a container made of crystal and glass, for example, JP2000-68780A discloses a container having a structure in which a crystal structure with a quartz-crystal vibrating piece and an outer frame integrally formed, a glass upper plate, and a glass lower plate are bonded by an anodic bonding method (Abstract, FIG. 1, FIG. 3, and the like).

In addition, as another example of a glass container, for example, JP2014-192644A discloses a container having a structure in which a lid and a base, which are constituted of borosilicate glass, are directly bonded together (paragraphs 0018, 0032, FIG. 1B, and the like).

Further, as an example of a crystal container, for example, JP2015-33035A discloses a container having a structure formed by bonding a lid wafer, a piezoelectric wafer, and a base wafer, which are constituted of crystal wafers, with a bonding material or by direct bonding and isolating this into individual piezoelectric devices (paragraphs 0072, 0075, 0076, FIG. 8, FIG. 9, and the like.)

Among the various kinds of containers described above, the most excellent one at the moment is the one that includes a ceramic base. However, as a reduction in thickness and size of piezoelectric devices progresses, it can be said that ceramic bases have limitations in structure, accuracy, and cost aspects. Therefore, a base with a novel structure that can replace the ceramic bases and can surpass the conventional containers made of glass and/or crystal described above is desired.

A need thus exists for a base for a piezoelectric device which is not susceptible to the drawback mentioned above.

### SUMMARY

According to an aspect of this disclosure, there is provided a base for a piezoelectric device. The base includes a substrate, a mounting pattern, a frame-shaped wall portion, an external mounting terminal, a contact portion, and a second metal film. The substrate is made of glass or crystal. The mounting pattern is for a piezoelectric element disposed on a first surface of the substrate. The frame-shaped wall portion is disposed in a part along an edge of the substrate on the first surface and made of a material identical to a material of the substrate. The wall portion is bonded to the substrate with a first metal film for intermetallic bonding. The external mounting terminal is disposed on a second surface that is an opposite surface from the first surface of the substrate. The contact portion is insulated from the first metal film in a region directly below the wall portion. The contact portion passes through the substrate to electrically connect the mounting pattern to the external mounting terminal. The second metal film is disposed in a part of a surface on the substrate side of the wall portion. The part is opposed to the contact portion. The second metal film forms intermetallic bonding with the contact portion to form airtightness of the contact portion.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a perspective view of a piezoelectric device according to a first embodiment, FIG. 1B is an end view taken along the dash-dotted line A-A in FIG. 1A, and FIG. 1C is an end view taken along the dash-dotted line B-B in FIG. 1A;

FIG. 2A is a plan view of a substrate of a base for a piezoelectric device according to the first embodiment, FIG. 2B is a bottom view of the substrate of the base for a piezoelectric device according to the first embodiment, FIG. 2C is a sectional drawing taken along the dash-dotted line C-C in FIG. 2A, and FIG. 2D is a sectional drawing taken along the dash-dotted line D-D in FIG. 2A;

FIG. 3A is a plan view of a wall portion of the base for a piezoelectric device according to the first embodiment, and FIG. 3B is a bottom view of the wall portion of the base for a piezoelectric device according to the first embodiment;

FIG. 4 is an enlarged plan view illustrating the arrangement relationship of a contact portion, a metal film, and the like of the base for a piezoelectric device according to the first embodiment;

FIGS. 5A to 5D are plan views of a fabrication process of the base for a piezoelectric device according to the first embodiment;

FIG. 6A is an enlarged plan view illustrating the arrangement relationship of a contact portion, a metal film, and the like of a base for a piezoelectric device according to a modification of the first embodiment, and FIG. 6B is an enlarged plan view illustrating the arrangement relationship of a contact portion, a metal film, and the like of a base for a piezoelectric device according to another modification of the first embodiment;

FIG. 7A is a plan view of a substrate of a base for a piezoelectric device according to a second embodiment, FIG. 7B is a bottom view of a wall portion of the base for a piezoelectric device according to the second embodiment, and FIG. 7C is an enlarged plan view illustrating the arrangement relationship of a contact portion, a metal film, and the like of the base for a piezoelectric device according to the second embodiment;

FIG. 8A is a plan view of a substrate of a base for a piezoelectric device according to a third embodiment, FIG. 8B is a bottom view of a wall portion of the base for a piezoelectric device according to the third embodiment, and FIG. 8C is an enlarged plan view illustrating the arrangement relationship of a contact portion, a metal film, and the like of the base for a piezoelectric device according to the third embodiment; and

FIGS. 9A to 9C are enlarged plan views illustrating the arrangement relationships of a contact portion, a metal film, and the like of a base for a piezoelectric device according to modifications of the third embodiment.

### DETAILED DESCRIPTION

The following describes a piezoelectric device and a base for a piezoelectric device used in the piezoelectric device of this disclosure in detail with reference to the drawings. This disclosure is not limited to the content described below and can be conveniently changed to the extent that the gist does not change. In addition, all the drawings used for each embodiment schematically illustrate the piezoelectric device and the base for a piezoelectric device according to this disclosure and are, for example, partially emphasized, enlarged, reduced, or omitted to deepen understanding. They may not accurately represent the reduced scale, shape, and the like of each component part. Furthermore, some numerical values used in each embodiment and its modification all indicate examples and can be changed variously as necessary. Then, identical reference numerals are attached to configurations common in the drawings.

### First Embodiment

### Structure of Piezoelectric Device

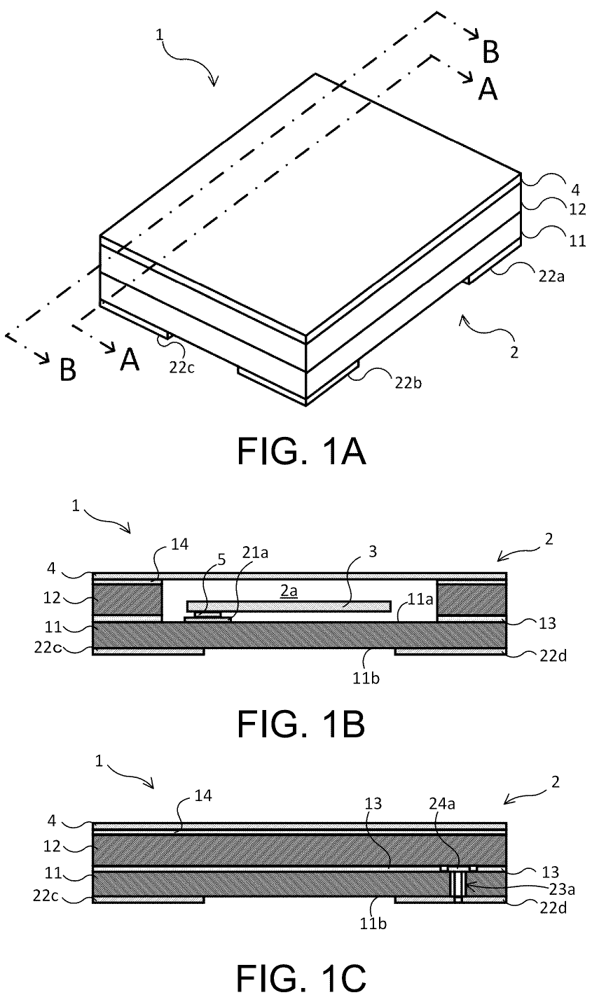

First, the basic structures of the piezoelectric device and the base for a piezoelectric device according to this disclosure will be described with reference to FIGS. 1A to 1C. Here, FIG. 1A is a perspective view of a piezoelectric device according to a first embodiment, FIG. 1B is an end view taken along the dash-dotted line A-A in FIG. 1A, and FIG. 1C is an end view taken along the dash-dotted line B-B in FIG. 1A.

As can be seen from FIGS. 1A to 1C, a piezoelectric device 1 has a base for a piezoelectric device 2 (hereinafter simply referred to as a base 2), a piezoelectric element 3 mounted in a mounting space 2a of the base 2, and a lid member 4 bonded to the base 2 to seal the piezoelectric element 3. In this embodiment, the piezoelectric device 1 is a crystal unit with the piezoelectric element 3 mounted as a quartz-crystal vibrating piece and a kind of electronic device used to initiate oscillation with high-frequency accuracy by utilizing a piezoelectric effect.

The base 2 has a flat plate-shaped substrate 11 made of glass or crystal, a wall portion 12 in the shape of a quadrilateral frame connected to the substrate 11 by intermetallic bonding, and a bonding metal film (first metal film) 13 that constitutes the intermetallic bonding between the substrate 11 and the wall portion 12. In addition, a sealing metal film 14 that bonds the lid member 4 to the wall portion 12 by intermetallic bonding is disposed on the wall portion 12 of the base 2 (at an upper side in a thickness direction of the piezoelectric device 1). Here, the material of the wall portion 12 is glass or crystal, which is the same material as the substrate 11. Further, the wall portion 12 is disposed in a part along an edge of the substrate 11 on a first surface (element mounting surface) 11a of the substrate 11. Note that bonding between the wall portion 12 and the lid member 4 is not limited to the one by the intermetallic bonding and may be bonding using, for example, a brazing material.

When the material of the substrate 11 and the wall portion 12 is crystal, a Z-cut plate or AT-cut plate is preferred for the crystal. Since each of the crystal Z-cut plate or the crystal AT-cut plate is a substrate that is mass-produced for crystal units, it is also advantageous in terms of cost. On the other hand, when the material of the substrate 11 and the wall portion 12 is glass, any given preferred glass, such as soda-lime glass, may be used.

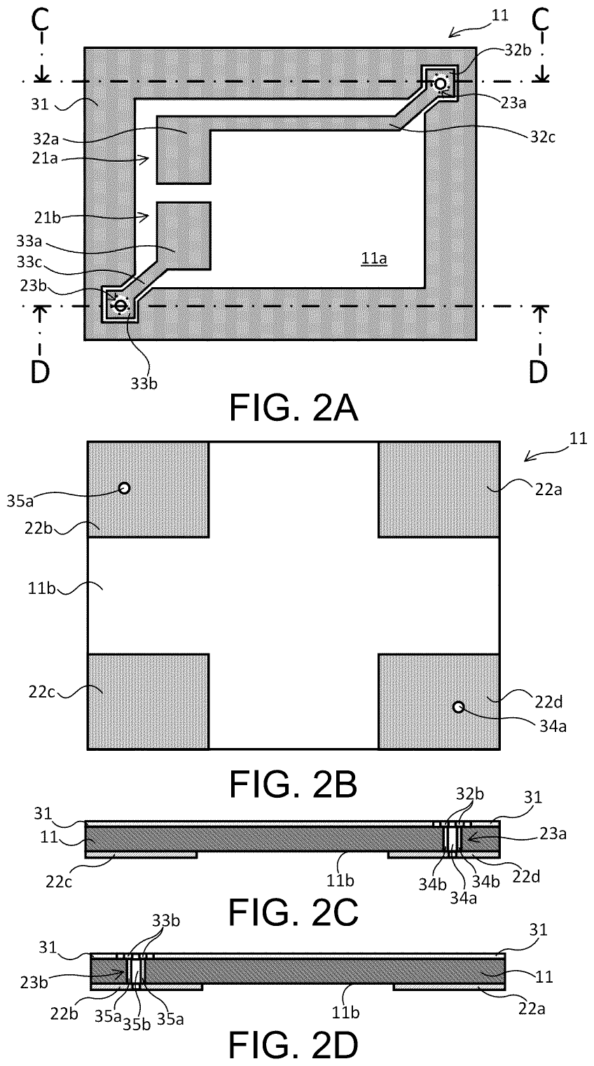

Furthermore, the base 2 has mounting patterns 21a and 21b for a piezoelectric element disposed to be separated from the bonding metal film 13 in a region inside a formation region of the bonding metal film 13 on the first surface 11a of the substrate 11. Especially, a conductive adhesive 5 is disposed in a mounting portion with a rectangular shape in planar view of each mounting pattern, and the piezoelectric element 3 is fixed to be mounted to each mounting pattern by the conductive adhesive 5. Note that details of the mounting patterns 21a and 21b will be described later with reference to FIG. 2A.

Moreover, the base 2 has four external mounting terminals 22a, 22b, 22c, and 22d, which are disposed on a second surface (bottom surface) 11b that is an opposite surface from the first surface 11a of the substrate 11. Each external mounting terminal is fixedly secured to a pad of a circuit board, on which the piezoelectric device 1 is mounted, via a bonding member, such as solder.

Furthermore, the base 2 has contact portions 23a and 23b disposed in a region directly below the wall portion 12 (at a lower side in the thickness direction of the piezoelectric device 1). Each contact portion passes through the substrate 11 and electrically connects one of the mounting patterns 21a and 21b to any of the four external mounting terminals 22a, 22b, 22c, and 22d. The specific connection configuration will be described later with reference to FIGS. 2A and 2B.

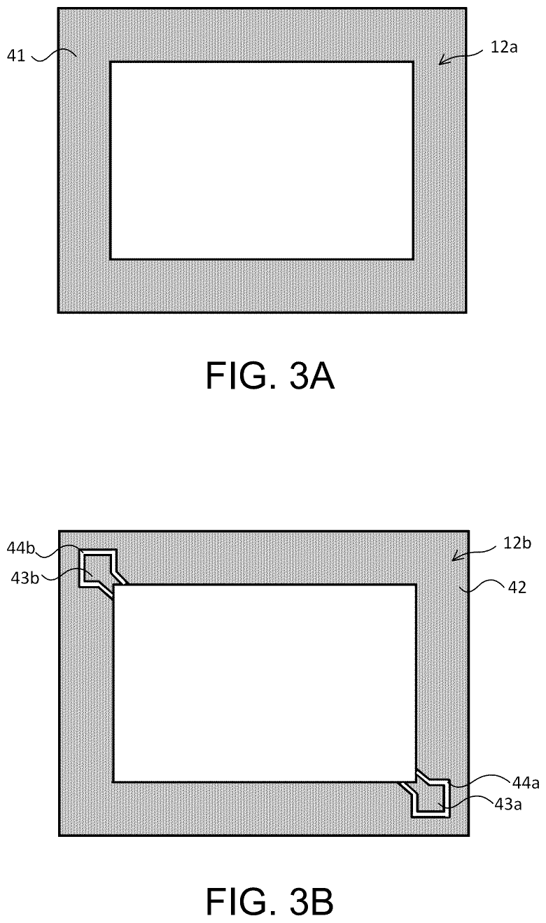

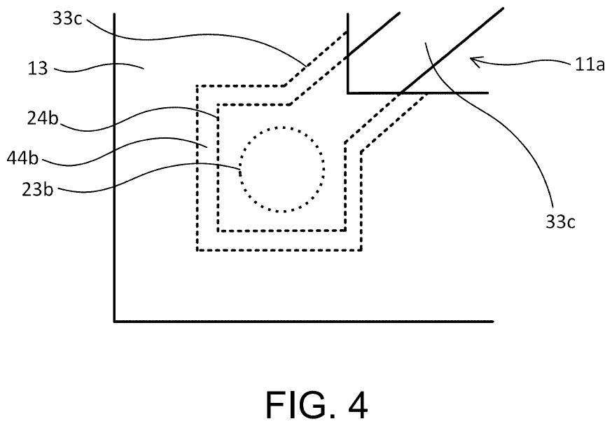

Additionally, the base 2 has airtight forming films (second metal films) 24a and 24b disposed in parts, which are opposed to the contact portions 23a and 23b, of a surface on a substrate side of the wall portion 12. Especially, each airtight forming film forms intermetallic bonding with each contact portion to be in contact with to form airtightness of each contact portion. The arrangement relationship between each airtight forming film and each contact portion that is in contact with the airtight forming film will be described later with reference to FIG. 2A, FIG. 3B, and FIG. 4.

### Structure of Base

Next, the structure of the substrate 11 side that constitutes the base 2 will be described with reference to FIGS. 2A to 2D. Here, FIG. 2A is a plan view of a substrate of a base for a piezoelectric device according to the first embodiment, FIG. 2B is a bottom view of the substrate of the base for a piezoelectric device according to the first embodiment, FIG. 2C is a sectional drawing taken along the dash-dotted line C-C in FIG. 2A, and FIG. 2D is a sectional drawing taken along the dash-dotted line D-D in FIG. 2A. Especially, FIGS. 2A to 2D illustrate the configuration of the substrate 11 in a state before the substrate 11 and the wall portion 12 are integrated by intermetallic bonding.

As illustrated in FIG. 2A, on the first surface 11a of the substrate 11, a substrate-side metal film 31 in the shape of an approximately quadrilateral frame is disposed in a part along the edge of the substrate 11. That is, the substrate-side metal film 31 is formed so as to surround an outer periphery of the first surface 11a of the substrate 11. Here, the substrate-side metal film 31 is bonded to a wall portion-side metal film described later by intermetallic bonding to constitute the bonding metal film 13 described above.

In addition, as illustrated in FIG. 2A, the mounting patterns 21a and 21b are disposed in an inner region with respect to a formation region of the substrate-side metal film 31 on the first surface 11a of the substrate 11. The mounting pattern 21a is constituted of a pad portion 32a to which the conductive adhesive 5 for fixing and holding the piezoelectric element 3 is applied, a substrate-side lid portion 32b with an approximately quadrilateral shape formed on the contact portion 23a at a corner of the substrate 11, and a wiring portion 32c that connects the pad portion 32a to the substrate-side side lid portion 32b. Similarly, the mounting pattern 21b is constituted of a pad portion 33a to which the conductive adhesive 5 for fixing and holding the piezoelectric element 3 is applied, a substrate-side lid portion 33b with an approximately quadrilateral shape formed on the contact portion 23b at a corner of the substrate 11, and a wiring portion 33c that connects the pad portion 33a to the substrate-side lid portion 33b. Here, the substrate-side lid portions 32b and 33b are disposed to be separated from the substrate-side side metal film 31 in two diagonally located regions of the four corners of the substrate-side metal film 31.

As illustrated in FIG. 2B, the four external mounting terminals 22a, 22b, 22c, and 22d are disposed on the second surface 11b of the substrate 11. The respective external mounting terminals are formed at the four corners of the substrate 11 and have rectangular planar shapes. In addition, in the external mounting terminals 22b and 22d, contact holes 34a and 35a constituting the contact portions 23a and 23b are formed in a state where they can be confirmed from the bottom surface.

As illustrated in FIG. 2C, the contact portion 23a is formed between the substrate-side lid portion 32b, which constitutes the mounting pattern 21a, and the external mounting terminal 22d. The contact portion 23a is constituted of a cylindrical contact hole 34a that passes through the substrate 11 and a contact hole wiring 34b formed inside the contact hole 34a. In this embodiment, while the contact hole wiring 34b is constituted of a metal film (membranous conductive body) formed along an internal surface (inner wall) of the contact hole 34a, for example, the contact hole 34a may be filled with a conductive body.

As illustrated in FIG. 2D, the contact portion 23b is formed between the substrate-side lid portion 33b, which constitutes the mounting pattern 21b, and the external mounting terminal 22b. The contact portion 23b is constituted of the cylindrical contact hole 35a that passes through the substrate 11 and a contact hole wiring 35b formed inside the contact hole 35a. In this embodiment, while the contact hole wiring 35b is constituted of a metal film (membranous conductive body) formed along an internal surface (inner wall) of the contact hole 35a, for example, the contact hole 35a may further be filled with a conductive body.

The substrate-side metal film 31, the mounting patterns 21a and 21b, the external mounting terminals 22a, 22b, 22c, and 22d, and the contact portions 23a and 23b may be constituted of laminated films with a three-layer structure of, for example, a chromium (Cr) film as a foundation film, a nickel (Ni) film or nickel-tungsten (NiW) alloy film as an intermediate film, and a gold (Au) film as an upper layer film. This is because the configuration including a nickel film or nickel-tungsten alloy film as the intermediate film can avoid the diffusion of chromium as the foundation film into the gold film as the upper layer film, thus conducting intermetallic bonding more properly. In addition, it is considered that laminated films with this three-layer structure can also avoid the diffusion of chromium into the gold film over time.

The substrate-side metal film 31, the mounting patterns 21a and 21b, the external mounting terminals 22a, 22b, 22c, and 22d, and the contact portions 23a and 23b may further have a titanium (Ti) film laminated on the gold film and an additional gold film laminated on the titanium film. This is because chromium may diffuse into the gold film even when a nickel or nickel-tungsten alloy is provided, and therefore, the titanium film can avoid the diffusion of chromium into the gold film at the uppermost layer, thus conducting intermetallic bonding still more properly. Also, in the case of laminated films with this five-layer structure, it is considered that the diffusion of chromium into the gold film can further be avoided over time.

Next, the structure of the wall portion 12 side that constitutes the base 2 will be described with reference to FIGS. 3A and 3B. Here, FIG. 3A is a plan view of a wall portion of the base for a piezoelectric device according to the first embodiment, and FIG. 3B is a bottom view of the wall portion of the base for a piezoelectric device according to the first embodiment. Especially, FIGS. 3A and 3B illustrate the configuration of the wall portion 12 in a state before the substrate 11 and the wall portion 12 are integrated by intermetallic bonding.

As illustrated in FIG. 3A, a metal film 41 for sealing is disposed along the wall portion 12 on a first surface 12a of the wall portion 12. That is, the metal film 41 is formed so as to cover the first surface 12a of the wall portion 12 entirely and bonded to a metal film contained in the lid member 4 by intermetallic bonding to constitute the sealing metal film 14 described above.

As illustrated in FIG. 3B, a wall portion-side metal film 42 in the shape of an approximately quadrilateral frame is disposed along the wall portion 12 on a second surface 12b of the wall portion 12. That is, the wall portion-side metal film 42 is formed so as to cover a large portion of the second surface 12b of the wall portion 12. In addition, wall portion-side lid portions 43a and 43b are disposed in two diagonally located regions of the four corners on the second surface 12b of the wall portion 12. Here, the wall portion-side lid portions 43a and 43b are formed to be separated from the wall portion-side metal film 42 by gaps 44a and 44b. Further, the wall portion-side lid portion 43a is opposed to the substrate-side lid portion 32b and a part of the wiring portion 32c, which are disposed on the substrate 11, and bonded to the substrate-side lid portion 32b and the wiring portion 32c by intermetallic bonding to constitute the airtight forming film 24a described above. Similarly, the wall portion-side lid portion 43b is opposed to the substrate-side lid portion 33b and a part of the wiring portion 33c, which are disposed on the substrate 11, and bonded to the substrate-side lid portion 33b and the wiring portion 33c by intermetallic bonding to constitute the airtight forming film 24b described above.

Similarly to the metal film and the like on the substrate 11 side, the wall portion-side metal film 42 and the wall portion-side lid portions 43a and 43b may be constituted of laminated films with a three-layer structure of, for example, a chromium (Cr) film as a foundation film, a nickel (Ni) film or nickel-tungsten (NiW) alloy film as an intermediate film, and a gold (Au) film as an upper layer film. This is because the configuration including a nickel film or nickel-tungsten alloy film as the intermediate film can avoid the diffusion of chromium as the foundation film into the gold film as the upper layer film, thus conducting intermetallic bonding more properly. In addition, it is considered that laminated films with this three-layer structure can also avoid the diffusion of chromium into the gold film over time.

Similarly to the metal film and the like on the substrate 11 side, the wall portion-side metal film 42 and the wall portion-side lid portions 43a and 43b may further have a titanium (Ti) film laminated on the gold film and an additional gold film laminated on the titanium film. This is because chromium may diffuse into the gold film even when a nickel or nickel-tungsten alloy is provided, and therefore, the titanium film can avoid the diffusion of chromium into the gold film at the uppermost layer, thus conducting intermetallic bonding still more properly. Also, in the case of laminated films with this five-layer structure, it is considered that the diffusion of chromium into the gold film can further be avoided over time.

Next, the positional relationship of the bonding metal film 13, the airtight forming film 24b, and the contact portion 23b in the base 2 will be described with reference to FIG. 4. Here, FIG. 4 is an enlarged plan view illustrating the arrangement relationship of a contact portion, a metal film, and the like of the base for a piezoelectric device according to the first embodiment. In FIG. 4, the positional relationship of the bonding metal film 13, the airtight forming film 24a, and the contact portion 23a in the base 2 is not illustrated, but it is the same as the positional relationship of the bonding metal film 13, the airtight forming film 24b, and the contact portion 23b in the base 2. Therefore, its explanation is omitted.

As can be seen from FIG. 4, the airtight forming film 24b, which is constituted by the intermetallic bonding of the substrate-side lid portion 33b, a part of the wiring portion 33c, and the wall portion-side lid portion 43b, is located on the contact portion 23b formed by passing through the substrate 11. Especially, since the contact portion 23b is located inside a formation region of the airtight forming film 24b, the contact portion 23b is not exposed between the substrate 11 and the wall portion 12, and the airtightness to the contact portion 23b is ensured with high accuracy. Then, the remaining portion of the wiring portion 33c (indicated by the solid lines in FIG. 4), which does not constitute the intermetallic bonding with the wall portion-side lid portion 43b, is exposed on the first surface 11a of the substrate 11.

In addition, as can be seen from FIG. 4, the bonding metal film 13, which is constituted by the intermetallic bonding of the substrate-side metal film 31 and the wall portion-side metal film 42, is separated from the airtight forming film 24b by the gap 44b. That is, the bonding metal film 13 is insulated from the airtight forming film 24b and the contact portion 23b. Therefore, the mounting pattern 21b for mounting the piezoelectric element 3 does not short-circuit with the bonding metal film 13, and the reliability of input or output related to the piezoelectric element 3 can be ensured.

### Method for Fabricating Base

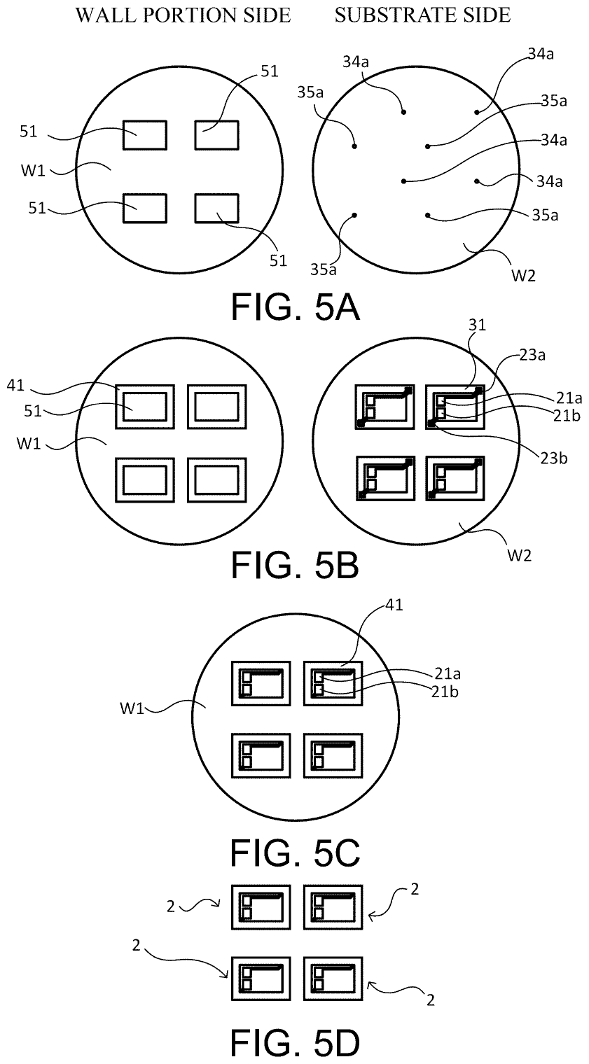

Next, the method for fabricating the base 2 will be described with reference to FIGS. 5A to 5D. Here, FIGS. 5A to 5D are plan views of a fabrication process of the base 2 for the piezoelectric device according to the first embodiment.

First, as illustrated in FIG. 5A, a crystal wafer W1 is prepared to form wall portions 12, and a crystal wafer W2 is prepared to form substrates 11. Subsequently, rectangular openings 51 that pass through the wafer W1 are formed in a matrix in the wafer W1 by known photolithography and etching techniques. In addition, contact holes 34a and 35a that pass through the wafer W2 are formed by known photolithography and etching techniques.

Next, as illustrated in FIG. 5B, the wafer W1 and the wafer W2 are patterned by known photolithography, film forming, and etching techniques. Specifically, metal films 41 for sealing are formed on a front side of the wafer W1 so as to surround circumferences of the openings 51. Although not illustrated in FIG. 5B, wall portion-side metal films 42 and wall portion-side lid portions 43a and 43b are formed on a back side of the wafer W1 so as to surround the openings 51 and be opposed to the metal films 41. Meanwhile, mounting patterns 21a and 21b and substrate-side metal films 31 in the shape of quadrilateral frames are formed on a front side of the wafer W2. In addition, although not illustrated in FIG. 5B, external mounting terminals 22a, 22b, 22c, and 22d are formed on a back side of the wafer W2 so as to be opposed to the mounting patterns 21a and 21b and the substrate-side metal films 31. Then, metal films (contact hole wirings 34b and 35b) are formed on the internal surfaces of the contact holes 34a and 35a to form contact portions 23a and 23b. While the sputtering method and photolithography technique can be used as the method for forming the external mounting terminals 22a, 22b, 22c, and 22d and the contact hole wirings 34b and 35b, the films of the external mounting terminals 22a, 22b, 22c, and 22d and the contact hole wirings 34b and 35b may be thickened by electrolytic plating or electroless plating.

Next, as illustrated in FIG. 5C, the wafer W1 and the wafer W2 are stacked in a predetermined positional relationship, heated in a vacuum chamber at a low pressure atmosphere, and pressurized with a predetermined force to bond the wafer W1 and the wafer W2. Here, the predetermined positional relationship is a state where the metal films 41 and the wall portion-side metal films 42 of the wafer W1 and the substrate-side metal films 31 overlap, and the mounting patterns 21a and 21b are exposed within the openings 51. In this case, one ends of the contact portions 23a and 23b are covered with the substrate-side lid portions 32b and 33b and the wall portion-side lid portions 43a and 43b, while the other ends of the contact portions 23a and 23b are covered with the external mounting terminals 22d and 22b.

Then, the above-described heating and pressurization process causes the wall portion-side metal films 42 and the substrate-side metal films 31 to be bonded by intermetallic bonding and causes parts of the mounting patterns 21a and 21b (the substrate-side lid portion 32b, a part of the wiring portion 32c, the substrate-side lid portion 33b, and a part of the wiring portion 33c) and the wall portion-side lid portions 43a and 43b to be bonded by intermetallic bonding. Accordingly, the bonding metal films 13 and the airtight forming films 24a and 24b are formed, ensuring the integration of the wafer W1 and the wafer W2 and the airtightness of the contact portions 23a and 23b.

Next, as illustrated in FIG. 5D, the bonded wafers described above are diced along predetermined lines using, for example, a dicing saw to obtain a plurality of isolated bases 2. This completes the fabrication process of the base 2 according to this embodiment. In the fabrication process, only one treatment is required for intermetallic bonding, therefore leading to a reduction in the number of processes and a reduction in fabrication costs. In addition, since the material used for the substrates 11 and the wall portions 12 is identical, which is crystal or glass, there is no deformation due to heating or the like, and the bonding positioning accuracy during the fabrication process can be improved, leading to the reduction in the number of processes and the reduction in fabrication costs.

As described above, the contact portions 23a and 23b arranged directly below the wall portion 12 are covered with the airtight forming films 24a and 24b in a state where the airtightness is ensured, and a base structure with excellent reliability, such as airtightness, can be realized.

### Modification of First Embodiment

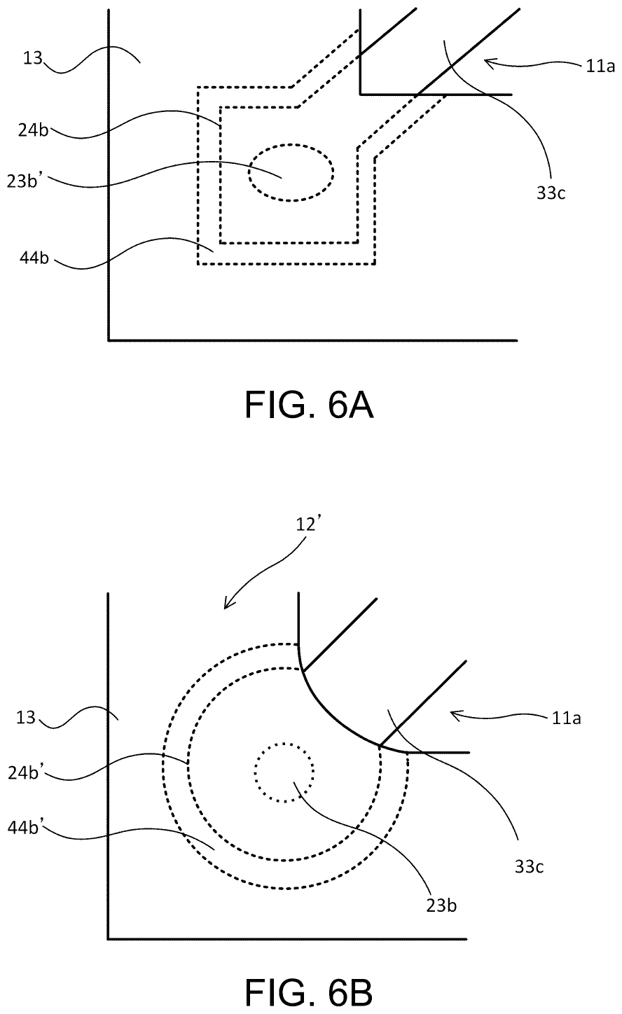

The planar shapes of the contact portions 23a and 23b and the airtight forming films 24a and 24b in the above embodiment are only examples, and other shapes may be used as long as electrical connection and airtightness can be ensured. For example, the shapes illustrated in FIGS. 6A and 6B may be used. Here, FIG. 6A is an enlarged plan view illustrating the arrangement relationship of a contact portion, a metal film, and the like of a base for a piezoelectric device according to a modification of the first embodiment, and FIG. 6B is an enlarged plan view illustrating the arrangement relationship of a contact portion, a metal film, and the like of a base for a piezoelectric device according to another modification of the first embodiment. Note that configurations identical to the configurations in the above embodiment are provided with identical reference numerals, and their explanations are omitted.

In the modification illustrated in FIG. 6A, the planar shape of a contact portion 23b′ is formed in an elliptical shape. That is, the contact portion 23b′ has an elliptical cylindrical shape. By adopting the shape, the volume of the contact portion 23b′ can be increased more without exposing the contact portion 23b′ from the airtight forming film 24b. In view of this, a reduction in resistance at the contact portion 23b′ can be ensured while airtightness is maintained.

In the modification illustrated in FIG. 6B, an airtight forming film 24b′, which covers the contact portion 23b having a circular planar shape, has an approximately circular planar shape similar to that of the contact portion 23b. In this case, a pad portion of a mounting pattern and a wall portion-side lid portion constituting the airtight forming film 24b′ are formed in an approximately circular shape. Then, an approximately annular gap 44b′ exists so as to surround the airtight forming film 24b′, and the insulation of the airtight forming film 24b′ and the contact portion 23b from the bonding metal film 13 is ensured. In the structure, the distance from the contact portion 23b to an end portion of the airtight forming film 24b′ can be kept approximately constant, making it possible to ensure the airtightness of the contact portion 23b stably.

In addition, a wall portion 12′ in FIG. 6B has a quadrilateral frame shape but has four inner corners with a rounded corner shape in planar view. Accordingly, the area of the four corner portions can be increased, and the formation area of the airtight forming film 24b′ can be increased more, enabling further improvement of airtightness. Although not illustrated, the four corners may have c-chamfered shapes, and even in this case, the formation area of the airtight forming film 24b′ can be increased more, enabling further improvement of airtightness.

### Second Embodiment

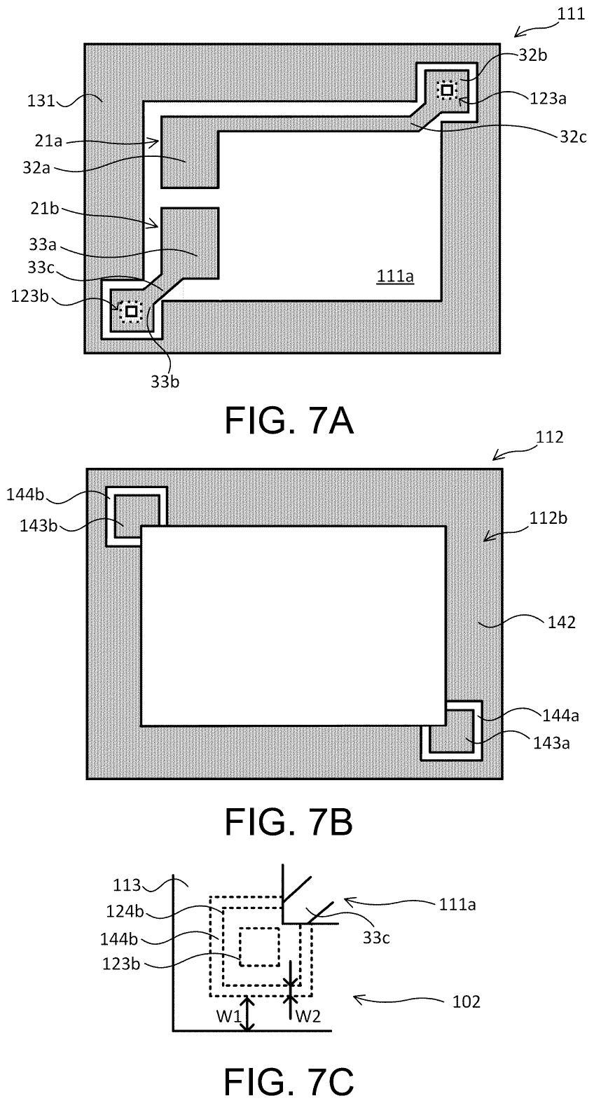

In the first embodiment, the contact portion has a cylindrical or elliptical cylindrical shape. However, a contact portion in the shape of a quadrilateral prism may be formed. As an example of this case, a case where the contact portion has a quadrilateral prismatic shape will be described as a second embodiment with reference to FIGS. 7A to 7C.

Here, FIG. 7A is a plan view of a substrate of a base for a piezoelectric device according to the second embodiment, FIG. 7B is a bottom view of a wall portion of the base for a piezoelectric device according to the second embodiment, and FIG. 7C is an enlarged plan view illustrating the arrangement relationship of a contact portion, a metal film, and the like of the base for a piezoelectric device according to the second embodiment. Note that the parts that differ from the first embodiment and its modification are basically described. As for identical contents, their explanations are omitted, and identical reference numerals are attached as their reference numerals in the drawings.

As illustrated in FIG. 7A, on a first surface 111a of a substrate 111 of the base according to the second embodiment, a substrate-side metal film 131 in the shape of an approximately quadrilateral frame is disposed in a part along an edge of the substrate 111. In addition, the mounting patterns 21a and 21b are disposed in an inner region with respect to a formation region of the substrate-side metal film 131 on the first surface 111a of the substrate 111. The mounting pattern 21a is constituted of the pad portion 32a, the substrate-side lid portion 32b, and the wiring portion 32c. The mounting pattern 21b is constituted of the pad portion 33a, the substrate-side lid portion 33b, and the wiring portion 33c. Furthermore, contact portions 123a and 123b in the shape of quadrilateral prisms, whose one ends are covered with the substrate-side lid portions 32b and 33b, are disposed on the substrate 111.

Although not illustrated, similarly to the first embodiment, four rectangular external mounting terminals are disposed at the four corners of the substrate 111 on a second surface on an opposite side from the first surface 111a of the substrate 111. Then, similarly to the first embodiment, the contact portions 123a and 123b are connected to two of the external mounting terminals.

As illustrated in FIG. 7B, a wall portion-side metal film 142 in the shape of an approximately quadrilateral frame is disposed along a wall portion 112 on a second surface 112b of the wall portion 112 in the shape of a quadrilateral frame of the base according to the second embodiment. That is, the wall portion-side metal film 142 is formed so as to cover a large portion of the second surface 112b of the wall portion 112. In addition, wall portion-side lid portions 143a and 143b are disposed in two diagonally located regions of the four corners on the second surface 112b of the wall portion 112. Here, the wall portion-side lid portions 143a and 143b are formed to be separated from the wall portion-side metal film 142 by gaps 144a and 144b.

In this embodiment, the wall portion-side lid portions 143a and 143b and the gaps 144a and 144b have different planar shapes from the wall portion-side lid portions 43a and 43b and the gaps 44a and 44b of the first embodiment. Specifically, the wall portion-side lid portions 143a and 143b do not have parts formed to be thin corresponding to parts of the wiring portions 32c and 33c and have planar shapes that are approximately quadrilateral in whole, with one of the four corners missing. In addition, the gaps 144a and 144b also have planar shapes that conform to the outer shapes of the wall portion-side lid portions 143a and 143b and are approximately quadrilateral annular shapes in whole, with one of the four corners missing.

Next, the positional relationship of a bonding metal film 113, an airtight forming film 124b, and a contact portion 123b in a base 102 according to the second embodiment will be described with reference to FIG. 7C. In FIG. 7C, the positional relationship of the bonding metal film 113, an airtight forming film, and a contact portion 123a in the base 102 is not illustrated, but it is the same as the positional relationship of the bonding metal film 113, the airtight forming film 124b, and the contact portion 123b in the base 102. Therefore, its explanation is omitted.

As can be seen from FIG. 7C, the airtight forming film 124b, which is constituted by the intermetallic bonding of a substrate-side lid portion 33b and the wall portion-side lid portion 143b, is located on the contact portion 123b formed by passing through the substrate 111. Especially, since the contact portion 123b is located inside a formation region of the airtight forming film 124b, the contact portion 123b is not exposed between the substrate 111 and the wall portion 112, and the airtightness to the contact portion 123b is ensured with high accuracy. Then, the wiring portion 33c, which does not constitute the intermetallic bonding with the wall portion-side lid portion 143b, is exposed on the first surface 111a of the substrate 111.

In addition, as can be seen from FIG. 7C, the bonding metal film 113, which is constituted by the intermetallic bonding of the substrate-side metal film 131 and the wall portion-side metal film 142, is separated from the airtight forming film 124b by the gap 144b. That is, the bonding metal film 113 is insulated from the airtight forming film 124b and the contact portion 123b. Therefore, the mounting pattern 21b for mounting a piezoelectric element does not short-circuit with the bonding metal film 113, and the reliability of input or output related to the piezoelectric element can be ensured.

In this embodiment, the contact portions 123a and 123b have planar shapes formed so as to have sides parallel to one side of the substrate 111 with a quadrilateral shape in planar view. Specifically, this embodiment is an example in which the contact portions 123a and 123b have quadrilateral prismatic shapes and, in planar view, quadrilateral shapes. Compared with a case of a cylindrical shape like the first embodiment, this case has an advantage in the following points.

First, compared with the contact portions 23a and 23b with circular shapes in planar view, in the contact portions 123a and 123b with quadrilateral shapes in planar view, the length of one side can be smaller than the diameters of the contact portions 23a and 23b. For example, assuming that the diameters of the contact portions 23a and 23b are 1 mm for the convenience of calculation, the contact portions 23a and 23b have circumferences of 3.14 mm and areas in planar view of 0.785 mm². In a quadrilateral shape with a circumference equal to this circumference, one side is 0.785 mm long, and in a quadrilateral shape with an equal area, one side is 0.886 mm long. That is, in order to ensure an identical outer peripheral length or area, a quadrilateral shape can have a smaller shape than a circular shape. In other words, the contact portions 123a and 123b with quadrilateral shapes in planar view can have increased outer peripheral length and area compared with the contact portions 23a and 23b with circular shapes in planar view. Accordingly, contact holes constituting the contact portions 123a and 123b can be enlarged further, making it easier to perform film formation inside the contact holes. In addition, since the internal areas (inner wall surface areas) of the contact holes increase, the wiring width of contact hole wiring is easily increased. In other words, the wiring width for reducing the wiring resistance of the contact hole wiring can be easily ensured. Furthermore, with the above configuration, the region of intermetallic bonding to ensure the airtightness of the contact portions 123a and 123b can be further expanded, thus realizing higher airtightness of the base 102.

Next, as can be seen from FIG. 7C, in the contact portions 123a and 123b with quadrilateral shapes in planar view, respective sides can be made parallel to the sides of the base 102 with a quadrilateral shape in planar view. Moreover, considering the comparison in the above numerical example in an opposite way in the comparison between a contact hole with a circular shape in planar view and a contact hole with a quadrilateral shape in planar view, when both contact holes have the same peripheral length and area, one side of the contact hole with a quadrilateral shape in planar view can be smaller than the diameter of the contact hole with a circular shape. This makes it easier to increase a width w1 of the bonding metal film 113, which bonds the substrate 111 to the wall portion 112 by intermetallic bonding by the amount that the size of the contact hole can be reduced. In addition, an insulation width w2, which is the distance between the bonding metal film 113 and the airtight forming films and 124b, is also made easier to increase. Therefore, the airtightness and insulation property related to the wall portion near the contact portions 123a and 123b can be improved.

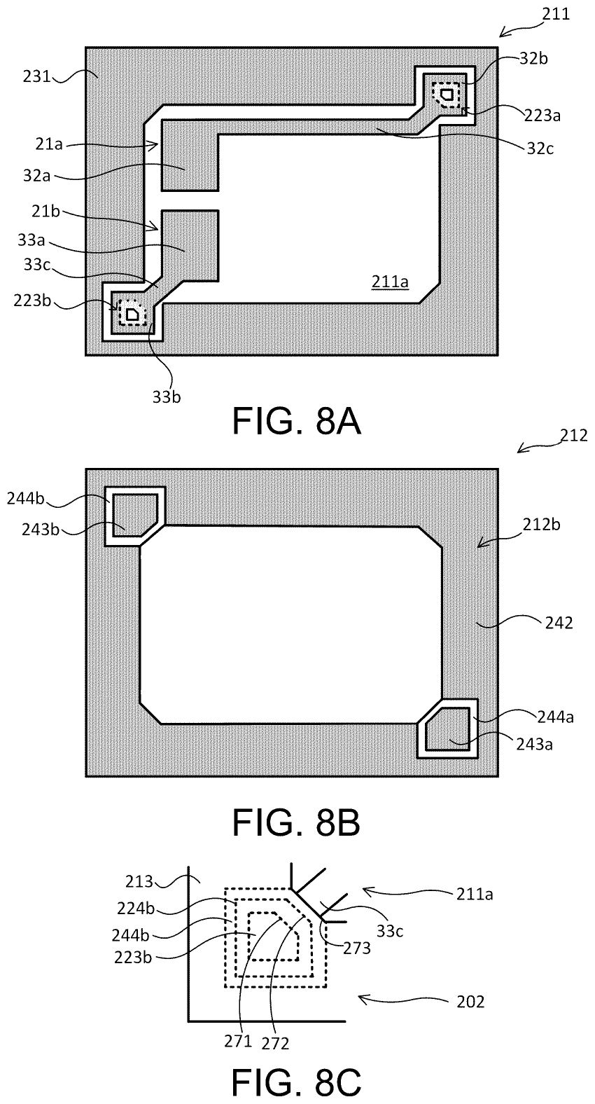

Note that the planar shapes of the contact portions 123a and 123b are not limited to quadrilateral shapes and may be other polygonal shape. For example, a triangle or a polygonal shape with five or more sides may be used. However, a pentagonal shape described later using FIG. 8, in which the center side of a substrate is c-chamfered, is as preferable as the quadrilateral shape.

### Third Embodiment

In the first embodiment, the contact portion has a cylindrical or elliptical cylindrical shape, and in the second embodiment, the contact portion has a quadrilateral prismatic shape. However, a contact portion in the shape of a polygonal prism may be formed. As an example of this case, a case where the contact portion has a polygonal prismatic shape will be described as a third embodiment with reference to FIGS. 8A to 8C.

Here, FIG. 8A is a plan view of a substrate of a base for a piezoelectric device according to the third embodiment, FIG. 8B is a bottom view of a wall portion of the base for a piezoelectric device according to the third embodiment, and FIG. 8C is an enlarged plan view illustrating the arrangement relationship of a contact portion, a metal film, and the like of the base for a piezoelectric device according to the third embodiment. Note that the parts that differ from the first embodiment, its modification, and the second embodiment are basically described. As for identical contents, their explanations are omitted, and identical reference numerals are attached as their reference numerals in the drawings.

As illustrated in FIG. 8A, on a first surface 211a of a substrate 211 of the base according to the third embodiment, a substrate-side metal film 231 in the shape of an approximately quadrilateral frame is disposed in a part along an edge of the substrate 211. The substrate-side metal film 231 is c-chamfered at two diagonally located corners of the four inner corners, unlike the substrate-side metal film 131 according to the second embodiment. This is to correspond to a wall portion 212 and a wall portion-side metal film 242 described later. In addition, the mounting patterns 21a and 21b are disposed in an inner region with respect to a formation region of the substrate-side metal film 231 on the first surface 211a of the substrate 211. The mounting pattern 21a is constituted of the pad portion 32a, the substrate-side lid portion 32b, and the wiring portion 32c. The mounting pattern 21b is constituted of the pad portion 33a, the substrate-side lid portion 33b, and the wiring portion 33c. Furthermore, contact portions 223a and 223b in the shape of pentagonal prisms, whose one ends are covered with the substrate-side lid portions 32b and 33b, are disposed on the substrate 211. In other words, the contact portions 223a and 223b have shapes, each with one of the four corners of a square c-chamfered.

Although not illustrated, similarly to the first embodiment, four rectangular external mounting terminals are disposed at the four corners of the substrate on a second surface on an opposite side from the first surface 211a of the substrate 211. Then, similarly to the first embodiment, the contact portions 223a and 223b are connected to two of the external mounting terminals.

As illustrated in FIG. 8B, unlike the wall portion 112 of the second embodiment, the wall portion 212 of the base according to the third embodiment has an outer shape in the shape of an approximately quadrilateral frame but has the four inner corners c-chamfered. That is, the wall portion 212 has a shape in which its four corners expand inward. In addition, a wall portion-side metal film 242 in the shape of an approximately quadrilateral frame is disposed along the wall portion 212 on a second surface 212b of the wall portion 212. That is, the wall portion-side metal film 242 is formed so as to cover a large portion of the second surface 212b of the wall portion 212. In addition, wall portion-side lid portions 243a and 243b are disposed in two diagonally located regions of the four corners on the second surface 212b of the wall portion 212. Here, the wall portion-side lid portions 243a and 243b are formed to be separated from the wall portion-side metal film 242 by gaps 244a and 244b.

In this embodiment, the wall portion-side lid portions 243a and 243b and the gaps 244a and 244b have different planar shapes from the wall portion-side lid portions 143a and 143b and the gaps 144a and 144b of the second embodiment. Specifically, the wall portion-side lid portions 243a and 243b have pentagonal planar shapes, each with one of the four corners of a quadrilateral shape c-chamfered. That is, the c-chamfered shape parts of the wall portion-side lid portions 243a and 243b are formed to correspond and be parallel to the c-chamfered shapes of the four inner corners of the wall portion 212. In addition, the gaps 244a and 244b also have planar shapes that conform to the outer shapes of the wall portion-side lid portions 243a and 243b and are pentagonal annular shapes. In view of this, the wall portion-side lid portions 243a and 243b are formed into island shapes separated from the wall portion-side metal film 242 by the gaps 244a and 244b.

Next, the positional relationship of a bonding metal film 213, an airtight forming film 224b, and a contact portion 223b in a base 202 according to the third embodiment will be described with reference to FIG. 8C. In FIG. 8C, the positional relationship of the bonding metal film 213, an airtight forming film, and a contact portion 223a in the base 202 is not illustrated, but it is the same as the positional relationship of the bonding metal film 213, the airtight forming film 224b, and the contact portion 223b in the base 202. Therefore, its explanation is omitted.

As can be seen from FIG. 8C, the airtight forming film 224b, which is constituted by the intermetallic bonding of a substrate-side lid portion 33b and the wall portion-side lid portion 243b, is located on the contact portion 223b formed by passing through the substrate 211. Especially, since the contact portion 223b is located inside a formation region of the airtight forming film 224b, the contact portion 223b is not exposed between the substrate 211 and the wall portion 212, and the airtightness to the contact portion 223b is ensured with high accuracy. Then, the wiring portion 33c, which does not constitute the intermetallic bonding with the wall portion-side lid portion 243b, is exposed on the first surface 211a of the substrate 211.

In addition, as can be seen from FIG. 8C, the bonding metal film 213, which is constituted by the intermetallic bonding of the substrate-side metal film 231 and the wall portion-side metal film 242, is separated from the airtight forming film 224b by the gap 244b. That is, the bonding metal film 213 is insulated from the airtight forming film 224b and the contact portion 223b. Therefore, the mounting pattern 21b for mounting a piezoelectric element does not short-circuit with the bonding metal film 213, and the reliability of input or output related to the piezoelectric element can be ensured.

Furthermore, as can be seen from FIG. 8 C, a c-chamfered part of the contact portion 223b (side 271), a c-chamfered part of the airtight forming film 224b (side 272), and a c-chamfered part of the inside of the wall portion 212 (side 273) are arranged to be parallel. Further, other parts of the contact portion 223b (sides other than the side 271) are formed to be parallel to an outer periphery of the wall portion 212. Thus, the presence of a c-chamfered part can increase the bonding area surrounding one end of the contact portion 223b (the formation region of the airtight forming film 224b) compared with a case where there is no rounding processing or no processing, ensuring the improvement in airtightness.

In this embodiment, the contact portions 223a and 223b have pentagonal prismatic shapes, which can improve the airtightness compared with a case of a cylindrical shape like the first embodiment. This is because the planar shape of the contact portion 223a and 223b becomes pentagonal, enabling the distance to the gaps 244a and 244b and the distance to the sides of the substrate 211 and the wall portion 212 to be ensured larger, compared with a circular shape having the same area. That is, when the shapes of the contact portions 223a and 223b are pentagonal prismatic shapes, the formation regions of the airtight forming films and 224b around the contact portions 223a and 223b can be enlarged compared with the case of a cylindrical shape. In addition, the distance to the end portion of the bonding metal film 213 where the intermetallic bonding is not formed can be ensured, enabling higher airtightness of the base 202 to be realized.

### Modification of Third Embodiment

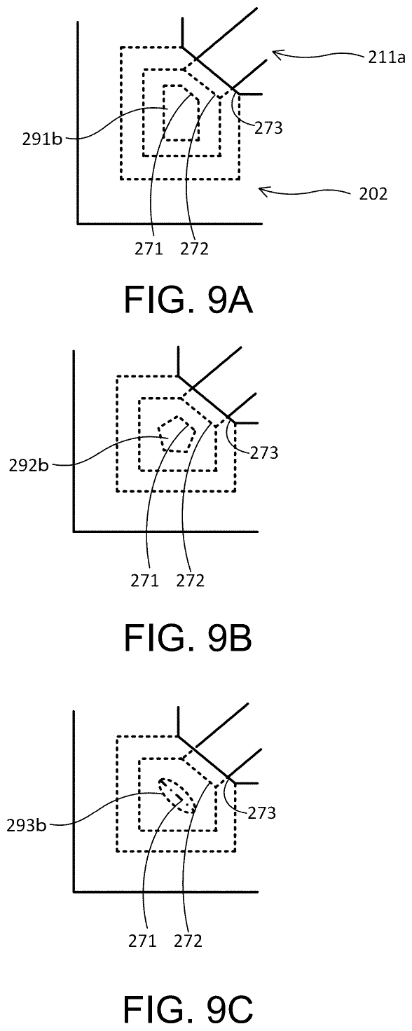

The shape of the contact portion is not limited to those described above but may take planar shapes, as illustrated in FIGS. 9A to 9C. Here, FIGS. 9A to 9C are enlarged plan views illustrating the arrangement relationships of a contact portion, a metal film, and the like of a base for a piezoelectric device according to modifications of the third embodiment.

As illustrated in FIG. 9A, a contact portion 291b may have a pentagonal shape with one corner of a rectangle c-chamfered. Even in this case, a c-chamfered part of the contact portion 291b (side 271), the c-chamfered part of the airtight forming film 224b (side 272), and the c-chamfered part of the inside of the wall portion 212 (side 273) are arranged to be parallel. Similarly to the third embodiment, this structure can increase the bonding area surrounding one end of the contact portion 291b, ensuring the improvement in airtightness.

Further, as illustrated in FIG. 9B, a contact portion 292b may have a regular pentagonal planar shape. Even in this case, one side of the contact portion 292b (side 271), the c-chamfered part of the airtight forming film 224b (side 272), and the c-chamfered part of the inside of the wall portion 212 (side 273) are arranged to be parallel. Similarly to the third embodiment, this structure can increase the bonding area surrounding one end of the contact portion 292b, ensuring the improvement in airtightness.

In addition, as illustrated in FIG. 9C, a contact portion 293b may have an elliptical planar shape. Even in this case, a longitudinal diameter of the contact portion 293b (side 271), the c-chamfered part of the airtight forming film 224b (side 272), and the c-chamfered part of the inside of the wall portion 212 (side 273) are arranged to be parallel. Similarly to the third embodiment, this structure can increase the bonding area surrounding one end of the contact portion 293b, ensuring the improvement in airtightness.

### Aspects of This Disclosure

A first aspect of this disclosure is a base for a piezoelectric device. The base includes a substrate, a mounting pattern, a frame-shaped wall portion, an external mounting terminal, a contact portion, and a second metal film. The substrate is made of glass or crystal. The mounting pattern is for a piezoelectric element disposed on a first surface of the substrate. The frame-shaped wall portion is disposed in a part along an edge of the substrate on the first surface and made of a material identical to a material of the substrate. The wall portion is bonded to the substrate with a first metal film for intermetallic bonding. The external mounting terminal is disposed on a second surface that is an opposite surface from the first surface of the substrate. The contact portion is insulated from the first metal film in a region directly below the wall portion. The contact portion passes through the substrate to electrically connect the mounting pattern to the external mounting terminal. The second metal film is disposed in a part of a surface on the substrate side of the wall portion. The part is opposed to the contact portion. The second metal film forms intermetallic bonding with the contact portion to form airtightness of the contact portion. With the configuration, the contact portion arranged directly below the wall portion is covered with the second metal film in a state where airtightness is ensured, and a base structure with excellent reliability, such as airtightness, can be realized.

According to a second aspect of this disclosure, in the first aspect, the second metal film is disposed to be separated from the first metal film in an inner region with respect to a formation region of the first metal film. With the configuration, the mounting pattern and the contact portion can be insulated from the first metal film for bonding between the substrate and the wall portion, and a short circuit in the base can be avoided.

According to a third aspect of this disclosure, in the first or second aspect, the contact portion is constituted of a cylindrical contact hole and contact hole wiring formed in the contact hole. The configuration can ensure airtightness of the contact portion while simplifying the fabrication process.

According to a fourth aspect of this disclosure, in the first or second aspect, the contact portion is constituted of a prismatic-shaped contact hole and contact hole wiring formed in the contact hole. With the configuration, the formation region of the second metal film forming intermetallic bonding around the contact portion can be enlarged, further enhancing the airtightness of the contact portion.

According to a fifth aspect of this disclosure, in any one of the first to fourth aspects, the wall portion has a quadrilateral frame shape, the first metal film is disposed in a frame shape corresponding to the wall portion, and the second metal film is disposed at any two of four corners of the first metal film. The configuration can improve positioning accuracy during intermetallic bonding while simplifying the fabrication process.

According to a sixth aspect of this disclosure, in any one of the first to fifth aspects, in the wall portion, four inner corners have rounded corner shapes in planar view. With the configuration, the formation region of the second metal film forming intermetallic bonding around the contact portion can be enlarged, further enhancing the airtightness of the contact portion.

According to a seventh aspect of this disclosure, in any one of the first to fifth aspects, in the wall portion, four inner corners have c-chamfered shapes in planar view. The formation region of the second metal film forming intermetallic bonding around the contact portion can be enlarged, further enhancing the airtightness of the contact portion.

According to an eighth aspect of this disclosure, in any one of the first to fourth aspects, the wall portion has a quadrilateral frame shape, in which four inner corners have c-chamfered shapes in planar view. The first metal film is disposed in a frame shape corresponding to the wall portion. The second metal film is disposed at any two of four corners of the first metal film. The contact portion has a shape with one of four corners of a quadrangle c-chamfered in planar view, and a corner portion of the c-chamfered shape is parallel to a c-chamfered part of the wall portion. The formation region of the second metal film forming intermetallic bonding around the contact portion can be enlarged, further enhancing the airtightness of the contact portion.

According to a ninth aspect of this disclosure, in the first or second aspect, the contact hole wiring is constituted of a conductive body filling an inside of the contact hole or a conductive body formed on an internal surface of the contact hole. With the configuration, the electric connection between the mounting pattern and the external mounting terminal can be performed more reliably.

According to a tenth aspect of this disclosure, in any one of the first to ninth aspects, the substrate has a quadrilateral shape in planar view, and a planar shape of the contact portion is a polygonal shape having a side parallel to one side of the quadrilateral substrate. With the configuration, planar dimensions of the contact hole constituting the contact portion can be increased, making it easier to perform film formation inside the contact hole. In addition, as the planar dimensions of the contact hole increase, the area of an internal surface (inner wall surface area) of the contact hole also increases, and furthermore, the wiring width for reducing the wiring resistance of the contact hole wiring constituting the contact hole is easily ensured. Then, with the configuration, the width of the first metal film that bonds the wall portion to the substrate can be widened, and the insulation width from the first metal film to the second metal film that makes the contact portion airtight can be widened.

An eleventh aspect of this disclosure is a piezoelectric device including a base according to any one of the first to tenth aspects, a piezoelectric element connected and fixed to the mounting pattern by a conductive member, and a lid member bonded to the base to seal the piezoelectric element. With the configuration, a piezoelectric device with excellent reliability, such as airtightness, can be provided.

The aspect of this disclosure provides the piezoelectric device including the above-described base, a piezoelectric element connected and fixed to the mounting pattern by a conductive member, and a lid member bonded to the base to seal the piezoelectric element.

With this disclosure, a base having a novel structure for a piezoelectric device and a piezoelectric device including the same can be provided.

The above effect is only exemplary for the convenience of explanation, and effects according to this disclosure are not limited to the above. In addition to the above effect, this disclosure can provide any effect described in this disclosure.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

### DESCRIPTION OF REFERENCE SIGNS

1 . . . piezoelectric device
2 . . . base for a piezoelectric device (base)
3 . . . piezoelectric element
4 . . . lid member
5 . . . conductive adhesive
11 . . . substrate
12 . . . wall portion
13 . . . bonding metal film (first metal film)
14 . . . sealing metal film
21a, 21b . . . mounting pattern
22a, 22b, 22c, 22d . . . external mounting terminal
23a, 23b . . . contact portion
24a, 24b . . . airtight forming film (second metal film)
31 . . . substrate-side metal film
41 . . . metal film
42 . . . wall portion-side metal film

What is claimed is:

1. A base for a piezoelectric device, comprising:
a substrate made of glass or crystal;
a mounting pattern for a piezoelectric element disposed on a first surface of the substrate;
a frame-shaped wall portion disposed in a part along an edge of the substrate on the first surface and made of a material identical to a material of the substrate, the wall portion being bonded to the substrate with a first metal film for intermetallic bonding;
an external mounting terminal disposed on a second surface that is an opposite surface from the first surface of the substrate;
a contact portion insulated from the first metal film in a region directly below the wall portion, the contact portion passing through the substrate to electrically connect the mounting pattern to the external mounting terminal; and
a second metal film disposed in a part of a surface on the substrate side of the wall portion, the part being opposed to the contact portion, the second metal film forming intermetallic bonding with the contact portion to form airtightness of the contact portion.

2. The base according to claim 1, wherein
the second metal film is disposed to be separated from the first metal film in an inner region with respect to a formation region of the first metal film.

3. The base according to claim 1, wherein
the contact portion is constituted of a cylindrical contact hole and a contact hole wiring formed in the contact hole.

4. The base according to claim 1, wherein
the contact portion is constituted of a prismatic-shaped contact hole and a contact hole wiring formed in the contact hole.

5. The base according to claim 1, wherein
the substrate has a quadrilateral shape in planar view,
the first metal film is disposed in a frame shape corresponding to the wall portion, and
the second metal film is disposed at any two of four corners of the first metal film.

6. The base according to claim 5, wherein
the wall portion has four inner corners having rounded corner shapes in planar view.

7. The base according to claim 5, wherein
the wall portion has four inner corners having c-chamfered shapes in planar view.

8. The base according to claim 4, wherein
the wall portion has a quadrilateral frame shape in which four inner corners have c-chamfered shapes in planar view,
the first metal film is disposed in a frame shape corresponding to the wall portion,
the second metal film is disposed at any two of four corners of the first metal film, and
the contact portion has a shape with one of four corners of a quadrangle c-chamfered in planar view, and a corner portion of the c-chamfered shape is parallel to a c-chamfered part of the wall portion.

9. The base according to claim 3, wherein
the contact hole wiring is constituted of a conductive body filling an inside of the contact hole or a conductive body formed on an internal surface of the contact hole.

10. The base according to claim 1, wherein
the substrate has a quadrilateral shape in planar view, and a planar shape of the contact portion is a polygonal shape having a side parallel to one side of the quadrilateral substrate.

11. A piezoelectric device comprising:
the base according to claim 1;
a piezoelectric element connected and fixed to the mounting pattern by a conductive member; and
a lid member bonded to the base to seal the piezoelectric element.
